(19) United States
(12) Patent Application Publication
(10) Pub. No.: US 2021/0011064 A1
(43) Pub. Date: Jan. 14, 2021

(54) PROCESSING DEVICE AND METHOD FOR CHANGING FUNCTION OF PINS

(71) Applicant: Wistron Corp., New Taipei City (TW)

(72) Inventors: Jun Xin QIU, New Taipei City (TW); Lei YANG, New Taipei City (TW); Rui Jing LI, New Taipei City (TW); Qiang MENG, New Taipei City (TW)

(21) Appl. No.: 16/683,400

(22) Filed: Nov. 14, 2019

(30) Foreign Application Priority Data
Jul. 11, 2019 (CN) 201910625689.X

(51) Int. Cl. G01R 27/02; G06F 13/42

(52) U.S. Cl. CPC G01R 27/02; G06F 2213/0042; G06F 13/4282

(57) ABSTRACT

A detection method for a USB Type-C connector is provided. The detection method is applied to a dual role port (DRP) device. The detection method includes the following steps: in response to the DRP device being in a Try. SRC state, detecting whether there is a sink device connected to the DRP device; in response to detecting a sink device connected to the DRP device, switching the current source provided to the pull-up resistor connected to the CC pin from the first current value to the second current value, and detecting again whether there is a sink device connected to the DRP device, wherein the first current value is greater than the second current value; and in response to detecting a sink device connected to the DRP device, the DRP device enters an Attached. SRC state.

### CROSS REFERENCE TO RELATED APPLICATIONS

This Application claims priority of CN Patent Application No. 201910625689.X filed on Jul. 11, 2019, the entirety of which is incorporated by reference herein.

### BACKGROUND OF THE INVENTION

### Field of the Invention

The invention generally relates to a detection technology for USB Type-C connector, and more particularly, to a detection technology for USB Type-C connector in which the current source provided to the pull-up resistor which is connected to the configuration channel (C) pin is switched from the default current value to the high current value to detect whether a sink device is connected to a USB Type-C connector of a dual role port (DRP) device.

### Description of the Related Art

In current USB Type-C technology, a dual role port (DRP) device can be used as a source device (provide power) or a sink device (receive power).

When the DRP device is used as a sink device, the DRP device is usually connected to an electronic device through a USB Type-C-to-USB Type-A cable. In the USB Type-C standard, the resistance of the pull-up resistor connected to the configuration channel (CC) pin of the USB Type-C connector of the USB Type-C-to-USB Type-A cable is set to 56K Ω. However, when the DRP device is connected to a computer device (source device) through a USB Type-C-to-USB Type-A cable, because the quality of the USB Type-C-to-USB Type-A cables on the market is uneven, the resistance of the pull-up resistor connected to the CC pin of the USB Type-C connector of the USB Type-C-to-USB Type-A cable may be not set to 56K Ω (e.g. the resistance may be 10K Ω). Therefore, when the USB Type-A connector of the USB Type-C-to-USB Type-A cable is suddenly unplugged from the computer device, the voltage drop on the pull-up resistor connected to the CC pin of the USB Type-C connector may fall within the effective voltage range 0.25V˜1.6V. As a result, the DRP device may assume that it is connected to a sink device and then enter an Attached.SRC state. When the DRP device is in the Attached.SRC state, the DRP device may output voltage to its Vbus pin. At that time, if the DRP device is connected to the computer device again, because both the DRP device and the computer device may indicate that it is a source device itself, and it may lead to the short circuit of the DRP device and the computer device and breaking the electronic elements of the DRP device and the computer device.

### BRIEF SUMMARY OF THE INVENTION

The invention provides processing devices and methods for changing the functions of pins to overcome the problems described above.

An embodiment of the invention provides a detection method for a USB Type-C connector. The detection method for a USB Type-C connector is applied to a dual role port (DRP) device. The detection method for a USB Type-C connector includes the following steps: in response to the DRP device being in a Try.SRC state, detecting whether there is a sink device connected to the DRP device; in response to detecting a sink device connected to the DRP device, switching the current source provided to the pull-up resistor connected to the CC pin from the first current value to the second current value, and detecting whether there is a sink device connected to the DRP device again, wherein the first current value is greater than the second current value; and in response to detecting a sink device connected to the DRP device, the DRP device enters an Attached. SRC state.

In some embodiments, the detection method for a USB Type-C connector further includes the following step: after switching the current source from the first current value to the second current value, and in response to detecting no sink device connected to the DRP device, the DRP device enters a TryWait.SNK state.

In some embodiments, the detection method for a USB Type-C connector further includes the following steps: detecting whether the voltage on the CC pin falls within an effective voltage range; in response to the voltage on the CC pin falling within the effective voltage range, determining that there is a sink device connected to the DRP device; and in response to the voltage on the CC pin not falling within the effective voltage range, determining that there is no sink device connected to the DRP device.

In some embodiments, in the detection method for a USB Type-C connector, the first current value is 80 μA and the second current value is 330 μA.

An embodiment of the invention provides a dual role port (DRP) device. The DRP device includes an USB Type-C port, and a control device. The USB Type-C port is connected to a USB Type-C connector. The control device is coupled to the USB Type-C port. In response to the DRP device being in a Try. SRC state, the control device detects whether there is a sink device connected to the DRP device. In response to detecting a sink device connected to the DRP device, the control device switches the current source provided to the pull-up resistor connected to the CC pin from the first current value to the second current value, wherein the first current value is greater than the second current value. After switching the current source from the first current value to the second current value, the control device detects whether there is a sink device connected to the DRP device again, and in response to the control device detecting that the sink device is connected to the DRP device, the DRP device enters an Attached. SRC state.

Other aspects and features of the invention will become apparent to those with ordinary skill in the art upon review of the following descriptions of specific embodiments of the DRP devices and detection methods for a USB Type-C connector.

### BRIEF DESCRIPTION OF THE DRAWINGS

The invention will become more fully understood by referring to the following detailed description with reference to the accompanying drawings, wherein:

FIG. 1 is a block diagram of a dual role port (DRP) device 100 according to an embodiment of the invention;

FIG. 2 is a schematic diagram illustrating the DRP device 100 connected to the computer device 200 through the USB Type-C-to-USB Type-A cable 300 according to an embodiment of the invention; and

FIG. 3 is a flow chart 3000 illustrating a detection method for the USB Type-C connector according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

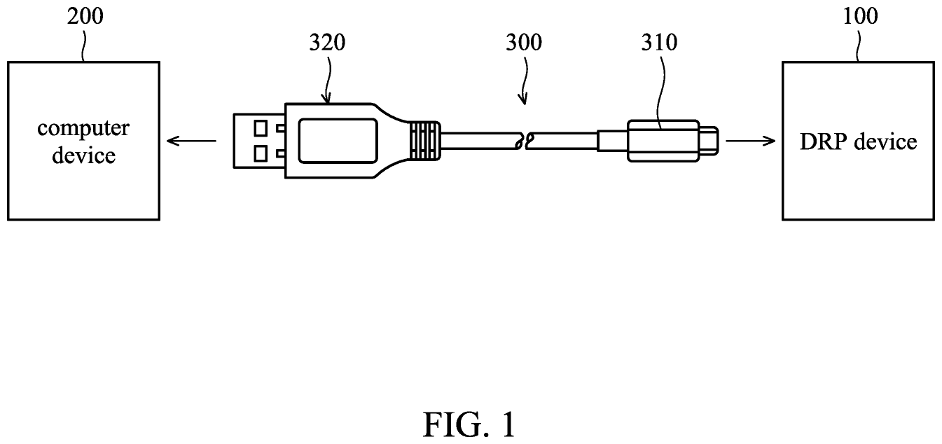

FIG. 1 is a block diagram of a dual role port (DRP) device 100 according to an embodiment of the invention. It should be noted that in order to clarify the concept of the invention, FIG. 1 presents a simplified block diagram in which only the elements relevant to the invention are shown. However, the invention should not be limited to what is shown in FIG. 1.

According to the embodiments of the invention, the DRP device 100 can be a source device or a sink device. In addition, the source device can be regarded as an Upstream Facing Port (UFP) device, and the sink device can be regarded as a Downstream Facing Port (DFP) device. The DRP device 100 may be a display device, but the invention should not be limited thereto. When the DRP device 100 needs to be connected to a computer device 200, the DRP device 100 may be connected to the computer device 200 through a USB Type-C-to-USB Type-A cable 300. The USB Type-C connector 310 of the USB Type-C-to-USB Type-A cable 300 is connected to the DRP device 100, and the USB Type-A connector 320 of the USB Type-C-to-USB Type-A cable 300 is connected to the computer device 200. In the embodiments of the invention, when the DRP device 100 is connected to the computer device 200, the DRP device 100 is a sink device, and the computer device is a source device.

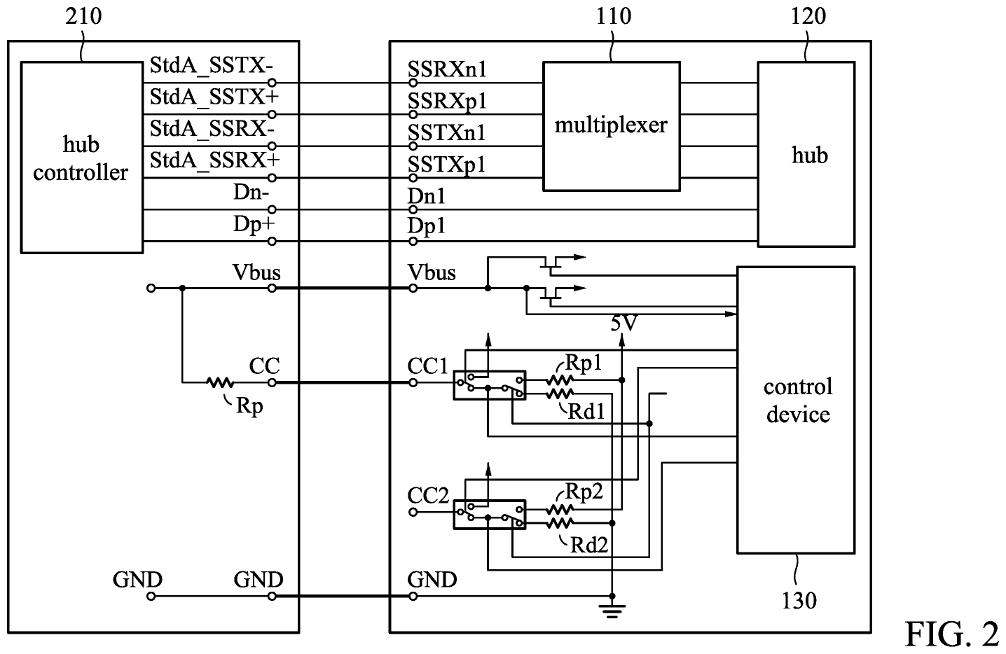

FIG. 2 is a schematic diagram illustrating the DRP device 100 connected to the computer device 200 through the USB Type-C-to-USB Type-A cable 300 according to an embodiment of the invention. It should be noted that in order to clarify the concept of the invention, FIG. 2 presents a simplified block diagram in which only the elements relevant to the invention are shown. However, the invention should not be limited to what is shown in FIG. 2. The DRP device 100 and the computer device 200 may comprise other elements.

As shown in FIG. 2, the DRP device 100 may include a multiplexer (MUX) 110, a hub 120, a control device 130, signal pins SSRXn1, SSRXp1, SSTXn1, SSTXp1, Dn1 and Dp1, a power source pin Vbus, a first CC pin CC1, a second CC pin CC2, a ground pin GND, a first pull-up resistor Rp1, a first pull-down resistor Rd1, a second pull-up resistor Rp2, and a second pull-down resistor Rd2. The signal pins SSRXn1, SSRXp1, SSTXn1, SSTXp1, Dn1 and Dp1, the power source pin Vbus, the first CC pin CC1, the second CC pin CC2, and the ground pin GND can be regarded as an USB Type-C port of the DRP device 100. The signal pins SSRXn1, SSRXp1, SSTXn1 and SSTXp1 are coupled to the MUX 110. The MUX 110 and the signal pins Dn1 and Dp1 are coupled to the hub 120. The power source pin Vbus, the first CC pin CC1, and the second CC pin CC2 are coupled to the control device 130. Because the DRP device 100 supports a two-way plug, two CC pins (first CC pin CC1 and the second CC pin CC2) and two groups of pull-up resistors and pull-down resistors are configured in the DRP device 100. The CC pin of the USB Type-C connector 310 of the USB Type-C-to-USB Type-A cable 300 may be coupled to the first CC pin CC1 or the second CC pin CC2.

As shown in FIG. 2, the computer device 200 may include a hub controller 210, signal pins StdA_SSRX−, StdA_SSRX+, StdA_SSTX−, StdA_SSTX+, Dn− and Dp−, the power source pin Vbus, a CC pin, a pull-up resistor Rp and a ground pin GND.

When the control device 130 of the DRP device 100 detects that a source device is connected to the DRP device 100 by detecting the CC pin, the DPR device 100 will be switched from an Unattached. SNK state to an AttachWait.SNK state. If the DRP device is pre-set to be a source device, when the DRP device 100 has been switched to the AttachWait.SNK state, the DRP device 100 will be switched from the AttachedWait.SNK state to a Try.SRC state. According to the standard of the USB Type-C, the Unattached. SNK state may mean that the DRP device 100 waits the appearance of a source device. The AttatchedWait state may mean that a SNK.Rp state is detected on the CC pin. The Try.SRC state may mean that the DRP device 100 detects whether there is a sink device connected to the DRP device 100.

According to an embodiment of the invention, when the DRP device 100 is in the Try.SRC state, the control device 130 may detect whether there is a sink device connected to the DRP device 100. If the control device 130 does not detect that there is a sink device connected to the DRP device 100, the DRP device 100 may enter a TryWait.SNK state. When the DRP device 100 enters the TryWait.SNK state, the control device 130 may detect whether there is a source device (e.g. computer device 200) connected to the DRP device 100. If the control device 130 detects that there is a source device (e.g. computer device 200) connected to the DRP device 100, the DRP device 100 may enter an Attached. SNK state to receive the power from the source device (e.g. computer device 200). If the control device 130 does not detect that there is a source device connected to the DRP device 100, the DRP device 100 may return to an Unattached. SNK state. In addition, the DRP device 100 can switch state between the Unattached.SNK state and an UnAttached.SRC state (i.e. perform DRP Toggle). That is to say, the DRP device 100 may change its role to be a source device or a sink device. According to the USB Type-C standard, TryWait.SNK state may means that the DRP device 100 fails to be a source device, and starts to detect whether there is a source device. The Attached. SNK state may mean that the DRP device 100 has been connected to a source device, and starts to be a sink device. UnAttached. SRC state may mean that the DRP device 100 wait the appearance of a sink device.

If the control device 130 detects that there is a sink device connected to the DRP device 100, the control device 130 may filter the noise, and detect whether there is a sink device connected to the DRP device 100 again. If the control device 130 does not detect there is a sink device connected to the DRP device 100, the DRP device 100 may enter the TryWait. SNK state, and perform the operations about the TryWait. SNK state discussed above. If the control device 130 detects there is a sink device connected to the DRP device 100, the control device 130 may switch the current source provided to the pull-up resistor connected to the CC pin of the USB Type-C connector 310 from the default current value (e.g. 80 μA) to another current value (e.g. 300 μA) which is greater than the default value, and detect whether there is a sink device connected to the DRP device 100 again. If the control device 130 still detects that there is a sink device connected to the DRP device 100 after the current source is switched, the DRP device 100 may enter an Attached. SRC state and output voltage to the sink device through its power source pin Vbus. If the DRP device 100 does not detect that there is a sink device connected to the DRP device 100 after the current source is switched, the DRP device 100 may enter a TryWait.SNK state and perform the operations about the TryWait.SNK state discussed above. According to the USB Type-C standard, the Attached.SRC state may mean that the DRP device 100 is connected to a sink device, and starts to be a source device.

In the embodiments of the invention, if the resistance of the pull-up resister connected to the CC pin of the USB Type-C connector 310 of the USB Type-C-to-USB Type-A cable 300 which is used to connect the DRP device 100 and the computer device 200 is not standard (default) 56K Ω, when the USB Type-A connector 320 of the USB Type-C-to-USB Type-A cable 300 is suddenly unplugged from the computer device 200, the control device 130 may switch the current source provided to the pull-up resistor Rp which is connected to the CC pin of the USB Type-C connector 310 from the default current value (e.g. 80 μA) to another current value which is greater than the default current value and detect whether there is a sink device connected to the DRP device again. Therefore, when the voltage on the CC pin falls within the effective voltage range because the resistance of the pull-up resistor Rp is too low, misjudgment of the control device 130 (i.e. the control device 130 may assume that the DRP device 100 is connected to a sink device) will be avoided.

TABLE 1

| | Resistor pull-up to | Resistor pull-up to | Current Source |
|---|---|---|---|
| DFP Advertisement | 4.75 V-5.5 V | 3.3 V + 5% | to1.7 V-5.5 V |
| Default USB power | 56 KΩ ± 20% | 36 KΩ ± 20% | 80 μA ± 20% |
| 1.5 A@5 V | 22 KΩ + 20% | 12 KΩ + 5% | 180 μA + 20% |
| 3.0 A@5 V | 10 KΩ ± 20% | 4.7 KΩ ± 20% | 330 μA ± 20% |

TABLE 2

| | |
|---|---|
| Current | Voltage range |

| | | |
|---|---|---|
| 3 | A | 2.60 V-0.85 V |
| 1.5 | A | 1.60 V-0.45 V |

| | |
|---|---|
| Default USB current | 1.60 V-0.25 V |

For example, referring to Table 1 and Table 2 (as shown above), table 1 shows the corresponding resistor values of the pull-up resistors of the DFP device and the corresponding current sources provided to the DFP device for different mode (or different USB power) in the USB Type-C standard, and table 2 shows the different voltage ranges (corresponding to different USB current) on the CC pin in the USB Type-C standard. In general, the standard (default) resistance of the pull-up resistor Rp connected to the CC pin of the USB Type-C-to-USB Type-A cable 300 is 56K Ω35 20%. That is to say, the standard (default) current source provided to the pull-up resistor Rp is 300 μA, and an effective voltage range corresponding to the standard (default) current source is 1.60V-0.25V. When the USB Type-A connector 320 of the USB Type-C-to-USB Type-A cable 300 is suddenly unplugged from the computer device 200, the control device 130 may detect whether the drop voltage on the pull-up resistor (i.e. the voltage on the CC pin) falls within the effective voltage range 1.60V-0.25V to determine whether there is a sink device connected to the DRP device 100. Therefore, if the resistance of the pull-up resistor connected to the CC pin of the USB Type-C connector 310 of the USB Type-C-to-USB Type-A cable 300 which is used to connect the DRP device 100 and the computer device 200 is 10K Ω (i.e. the pull-up resistor is not the standard pull-up resistor), when the USB Type-A connector 320 of the USB Type-C-to-USB Type-A cable 300 is suddenly unplugged from the computer device 200, the drop voltage on the pull-up resistor (i.e. the voltage on the CC pin) may fall within the effective voltage range 1.60V-0.25V. As a result, misjudgment of the control device 130 may occur (i.e. the control device 130 may assume that the DRP device 100 is connected to a sink device). However, in the embodiments of the invention, when the control device 130 switches the current source provided to the pull-up resistor Rp connected to the CC pin of the USB type-C connector 310 of the USB Type-C-to-USB Type-A cable 300 from a default current value (80 μA) to another current value (e.g. 300 μA), the effective voltage range may be changed to 2.60V-0.85V corresponded to the current value 300 μA. Therefore, when the control device 130 detects whether there is sink device connected to the DRP device 100 again, the control device 130 may detect correct result. That is to say, if the voltage on the CC pin falls in the voltage range 2.60V-0.85V, the control device 130 may determine that there is a sink device connected to the DRP device 100. On the other hand, if the voltage on the CC pin does not fall in the voltage range, the control device 130 may determine that there is no sink device connected to the DRP device 100. It should be noted that in the current USB Type-C standard, the maximum setting value of the current source is 330 μA, and therefore, if the current value is set (switched) to 330 μA, all conditions of the pull-up resistor Rp as defined in the USB Type-C standard will be met.

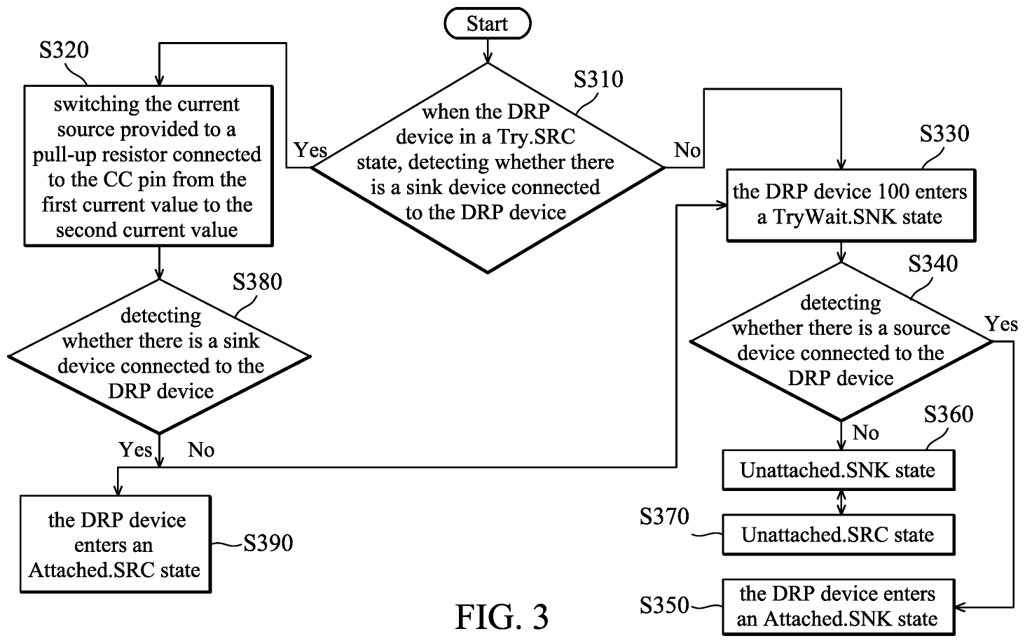

FIG. 3 is a flow chart 3000 illustrating a detection method for the USB Type-C connector according to an embodiment of the invention. The detection method for the USB Type-C connector can be applied to the DRP device 100. As shown in FIG. 3, in step S310, when the DRP device 100 in a Try. SRC state, the control device of the DRP device 100 may detect whether there is a sink device connected to the DRP device 100. When the control device of the DRP device 100 detects that there is a sink device connected to the DRP device 100, step S320 is performed. In step S320, the control device of the DRP device 100 may switch the current source provided to a pull-up resistor connected to the CC pin from the first current value (i.e. default current value) to the second current value, wherein the second current value is greater than the first current value. When the control device of the DRP device 100 does not detect that there is a sink device connected to the DRP device 100, step S330 is performed. In step S330, the DRP device 100 may enter a TryWait.SNK state.

In step S340, the control device of the DRP device 100 may detect whether there is a source device connected to the DRP device 100. If the control device of the DRP device 100 detects that there is a source device connected to the DRP device 100, step S350 is performed. In step S350, the DRP device 100 may enter an Attached.SNK state and accept the power from the source device. If the control device of the DRP device 100 does not detect that there is a source device connected to the DRP device, step S360 is performed. In step S360, the DRP device 100 may return to an Unattached.SNK state. In step S370, the DRP device 100 may switch state between the Unattached.SNK state and an UnAttached.SRC state (i.e. perform the DRP Toggle). That is to say, the DRP device 100 may change its role to be a source device or a sink device.

In step S380, when the current source has been switched from the first current value to the second current value, the control device of the DRP device 100 may detect whether there is a sink device connected to the DRP device 100 again. If the control device of the DRP device detects that there is a sink device connected to the DRP device, step S390 is performed. In step S390, the DRP device 100 may enter an Attached.SRC state. If the control device does not detect that there is a sink device connected to the DRP device 100 step S330 is performed, i.e. the DRP device 100 may enter a TryWait.SNK state.

According to the embodiments of the invention, in step S310, if the control device of the DRP device 100 detects that there is a sink device connected to the DRP device 100, the control device of the DRP device 100 may filter the noise first, and detect whether there is a sink device connected to the DRP device 100 again. Only if the control device of the DRP device 100 detects that there is a sink device connected to the DRP device 100, step S320 may be performed. If the control device of the DRP device 100 does not detect that there is a sink device connected to the DRP device 100, step S330 will be performed.

According to the embodiments of the invention, in the detection method for the USB Type-C connector, the control device of the DRP device 100 may determine whether the voltage on the CC pin falls within an effective voltage range. If the voltage on the CC pin falls within the effective voltage range, the control device of the DRP device 100 may determine that there is a sink device connected to the DRP device 100. If the voltage on the CC pin does not fall within the effective voltage range, the control device of the DRP device 100 may determine that there is no sink device connected to the DRP device 100.

According to the detection method for the USB Type-C connector, if the controller of the DRP device 100 detects that there is a sink device connected to the DRP device 100, the controller of the DRP device 100 may switch the current source provided to the pull-up resistor connected to the CC pin of the USB Type-C connector from a default current value (80 μA) to another current value which greater than the default current value, and detect whether there is a sink device connected to the DRP device again. Therefore, when the voltage on the CC pin falls within the effective voltage range because the resistance of the pull-up resistor Rp is too low (i.e. the resistance of the pull-up resistor Rp connected to the CC pin of the USB Type-C connector of the USB Type-C-to-USB Type-A cable is not standard (default) 56 K Ω), misjudgment of the control device 130 (i.e. the control device 130 may assume that the DRP device 100 is connected to a sink device) will be avoided.

Use of ordinal terms such as “first”, “second”, “third”, etc., in the disclosure and claims is for description. It does not by itself connote any order or relationship.

The steps of the method described in connection with the aspects disclosed herein may be embodied directly in hardware, in a software module executed by a processor, or in a combination of the two. A software module (e.g., including executable instructions and related data) and other data may reside in a data memory such as RAM memory, flash memory, ROM memory, EPROM memory, EEPROM memory, registers, a hard disk, a removable disk, a CD-ROM, or any other form of computer-readable storage medium known in the art. A sample storage medium may be coupled to a machine such as, for example, a computer/processor (which may be referred to herein, for convenience, as a “processor”) such that the processor can read information (e.g., code) from and write information to the storage medium. A sample storage medium may be integral to the processor. The processor and the storage medium may reside in an ASIC. The ASIC may reside in user equipment. Alternatively, the processor and the storage medium may reside as discrete components in user equipment. Moreover, in some aspects any suitable computer-program product may comprise a computer-readable medium comprising codes relating to one or more of the aspects of the disclosure. In some aspects a computer program product may comprise packaging materials.

The above paragraphs describe many aspects. Obviously, the teaching of the invention can be accomplished by many methods, and any specific configurations or functions in the disclosed embodiments only present a representative condition. Those who are skilled in this technology will understand that all of the disclosed aspects in the invention can be applied independently or be incorporated.

While the invention has been described by way of example and in terms of preferred embodiment, it should be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A detection method for a USB Type-C connector, applied to a dual role port (DRP) device, and comprising:
in response to the DRP device being in a Try.SRC state, detecting whether there is a sink device connected to the DRP device;
in response to detecting the sink device connected to the DRP device, switching a current source provided to a pull-up resistor connected to a CC pin from a first current value to a second current value, and detecting whether there is the sink device connected to the DRP device again, wherein the first current value is greater than the second current value; and
in response to detecting the sink device connected to the DRP device, the DRP device enters an Attached. SRC state.

2. The detection method for the USB Type-C connector of claim 1, further comprising:
after switching the current source from the first current value to the second current value, and in response to detecting no sink device connected to the DRP device, the DRP device enters a TryWait.SNK state.

3. The detection method for the USB Type-C connector of claim 1, wherein the step of detecting whether there is the sink device connected to the DRP device again comprises:
detecting whether a voltage on the CC pin falls within an effective voltage range;
in response to the voltage on the CC pin falling within the effective voltage range, determining that there is the sink device connected to the DRP device; and
in response to the voltage on the CC pin not falling within the effective voltage range, determining that there is no sink device connected to the DRP device.

4. The processing device detection method for the USB Type-C connector of claim 1, wherein the first current value is 80 μA and the second current value is 330 μA.

5. A dual role port (DRP) device, comprising:
an USB Type-C port, connected to a USB Type-C connector; and
a control device, coupled to the USB Type-C port;
wherein in response to the DRP device being in a Try. SRC state, the control device detects whether there is a sink device connected to the DRP device;
wherein in response to detecting the sink device connected to the DRP device, the control device switches a current source provided to a pull-up resistor connected to a CC pin from a first current value to a second current value, wherein the first current value is greater than the second current value; and
after switching the current source from the first current value to the second current value, the control device detects whether there is the sink device connected to the DRP device again, and in response to the control device detecting that the sink device is connected to the DRP device, the DRP device enters an Attached. SRC state.

6. The DRP device of pins of claim 5, wherein after switching the current source from the first current value to the second current value, in response to the control device detecting there is no sink device connected to the DRP device, the DRP device enters a TryWait.SNK state.

7. The DRP device of pins of claim 5, wherein the control device detects whether a voltage on the CC pin falls within an effective voltage range, wherein in response to the voltage on the CC pin falling within the effective voltage range, the control device determines that there is the sink device connected to the DRP device;
and in response to the voltage on the CC pin not falling within the effective voltage range, the control device determines that there is no sink device connected to the DRP device.

8. The DRP device of claim 5, wherein the first current value is 80 μA and the second current value is 330 μA.
